(19) United States
(12) Patent Application Publication
(10) Pub. No.: US 2009/0315185 A1
(43) Pub. Date: Dec. 24, 2009

(54) SELECTIVE ELECTROLESS METAL DEPOSITION FOR DUAL SALICIDE PROCESS

(76) Inventors: Boyan Boyanov, Portland, OR (US); Ramanan Chebiam, Hillsboro, OR (US)

Correspondence Address: CENTURY IP GROUP, INC. [Intel], C/O CPA GLOBAL, P.O BOX 52050, MINNEAPOLIS, MN, 55402, US

(21) Appl. No.: 12/143,248

(22) Filed: Jun. 20, 2008

(51) Int. Cl. H01L 23/48; H01L 21/44

(52) U.S. Cl. 257/768; 438/664; 257/E29.161

(57) ABSTRACT

A method for forming dual salicide contacts includes depositing a low or mid-gap work function metal selectively on an NMOS source/drain (S/D) region of a semiconductor device via electroless deposition; depositing a high work function metal selectively over the low work function metal and a PMOS source/drain (S/D) region of a semiconductor device via electroless deposition; annealing the semiconductor device to form a silicide of the low work function metal over the NMOS source/drain (S/D) region and a silicide of the high work function metal over the PMOS source/drain (S/D) region; and performing a SALICIDE etch to remove the unreacted metals from all regions of the substrate.

### BACKGROUND

Salicide formation for both NMOS and PMOS devices typically involves blanket metal deposition via plasma vapor deposition (PVD) over the entire wafer. The metal used is typically a midgap work function (WF) metal with a moderately high Schottky barrier height for both PMOS and NMOS devices. There is a need to reduce the Schottky barrier height of NMOS and PMOS devices.

### BRIEF DESCRIPTION OF THE DRAWINGS

Embodiments of the present invention are understood by referring to the figures in the attached drawings, as provided below.

FIG. 1 shows the Schottky barrier height of various metals and metal alloys as a function of metal work function, in accordance with one embodiment.

FIG. 2 illustrates a process flow for the formation of midgap work function (WF) silicide source/drain contacts, in accordance with one embodiment.

FIG. 3 shows a device fabricated according to the process flow of FIG. 2.

FIG. 4 illustrates an exemplary process flow for the formation of selective deposition silicide source/drain contacts according to one embodiment.

FIGS. 5A-5D show various stages of the formation of selective deposition silicide source/drain contacts according to one embodiment.

FIG. 6 shows the energy band structure leading to electroless deposition of a low or mid-gap WF metal on NMOS but not on PMOS according to one embodiment.

FIG. 7 shows the energy band structure leading to electroless deposition of a high WF metal non-selectively on both on NMOS and PMOS source/drain contacts according to one embodiment.

Features, elements, and aspects of the invention that are referenced by the same numerals in different figures represent the same, equivalent, or similar features, elements, or aspects, in accordance with one or more embodiments.

### DETAILED DESCRIPTION OF EXEMPLARY EMBODIMENTS

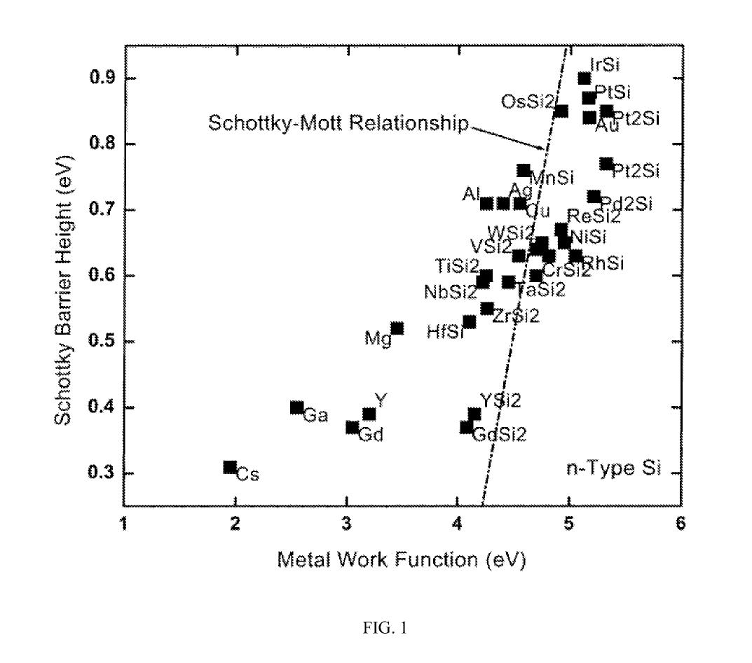

FIG. 1 shows experimentally measured Schottky barrier heights of various metals and metal alloys on n type Si as a metal work function (WF) or electronegativity. As shown, in a low WF metal, the metal's WF lies above the semiconductor band gap. In a midgap WF metal, the metal's WF lies near the middle of the semiconductor bandgap. A high WF metal, in contrast, has a reduction potential below the valence band edge of the semiconductor bandgap. Metals and metal silicide alloys toward the upper portion of the plot are better for low-resistance PMOS contacts, whereas metals and metal silicide alloys toward the bottom of the plot are better for low-resistance NMOS contacts. Therefore, a different metal deposition and salidation may be preferred for PMOS and NMOS device contacts to provide low-resistance.

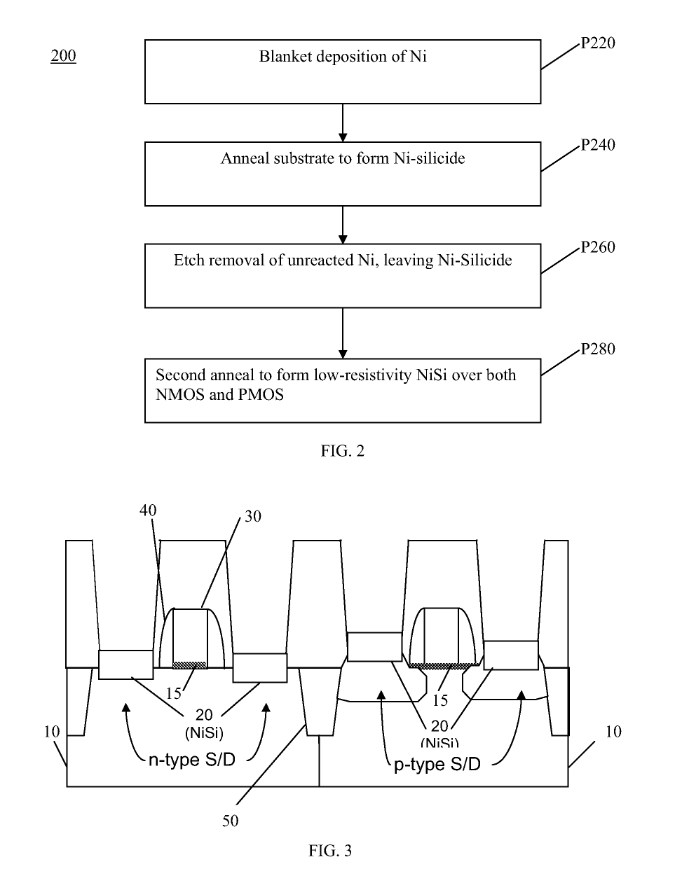

FIG. 2 illustrates a process flow for the formation of midgap WF silicide source/drain contacts, in accordance with one embodiment. FIG. 3 shows the device structure resulting from the process flow of FIG. 2. Process flow 200 begins with a blanket deposition of a midgap metal (P220). The semiconductor S/D regions are exposed directly to the deposited metal, whereas the remaining surface may be substantially coated with a protective mask, or material that does not react with the metal to form a silicide. The substrate is subjected to an annealing (P240) at elevated temperature to form Ni-silicide on the exposed S/D regions of the substrate, followed by an etch removal (P260) of unreacted metal, leaving a silicide, such as, Ni-silicide. A second annealing (P280) forms an ohmic contact of, for example, low-resistivity Ni-Silver on both the NMOS and PMOS S/D regions.

Referring to FIG. 3, a semiconductor (e.g., Si or SiGe) substrate may have separate n-type and p-type source/drain (S/D) regions separated by an isolation region 50. Within each n- or p-type region, the source (S) and drain (D) are spaced apart from each other by a channel 15, over which a gate electrode 30 is deposited, which may also insulate spacers 40 deposited on either side thereon to prevent conductive contact between gate 40 and S/D contact regions on which NiSi (Ni-silicide) contacts are deposited, by way of Ni overcoating, annealing, unreacted metal removal and further annealing to form an ohmic contact.

As indicated above, the metal used to form a silicide may be Ni in accordance with one or more embodiments. It is noteworthy, however, that any other type of suitable element, metal or compound with characteristics similar to a midgap metal with a moderately high Schottky barrier height for both PMOS and NMOS devices may be also used, so that high contact resistance may be achieved (see FIG. 1).

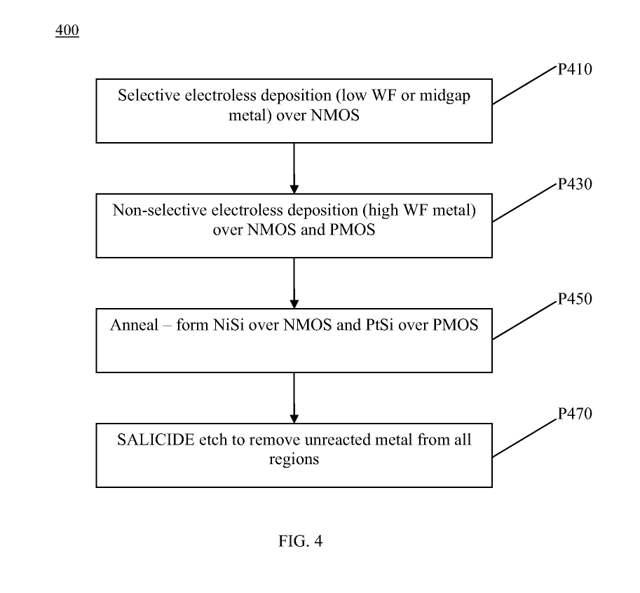

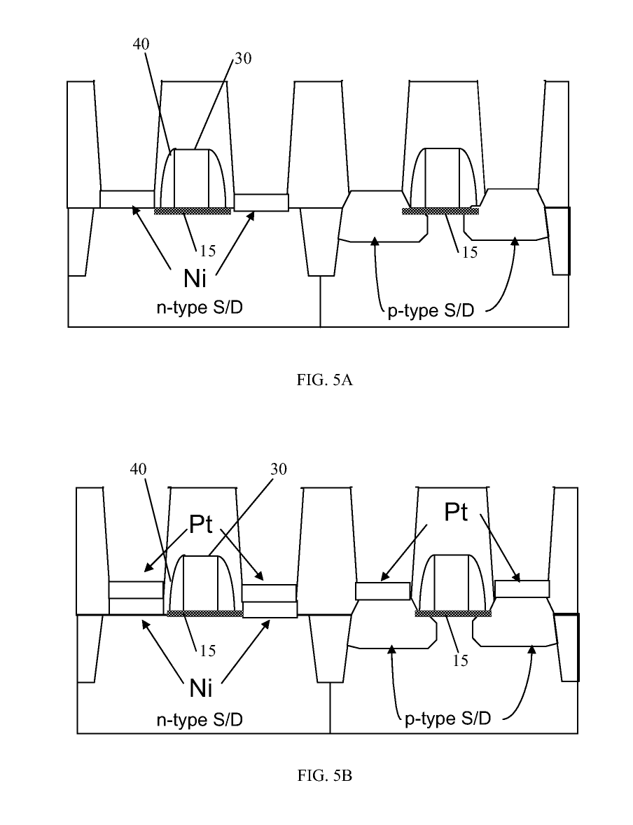

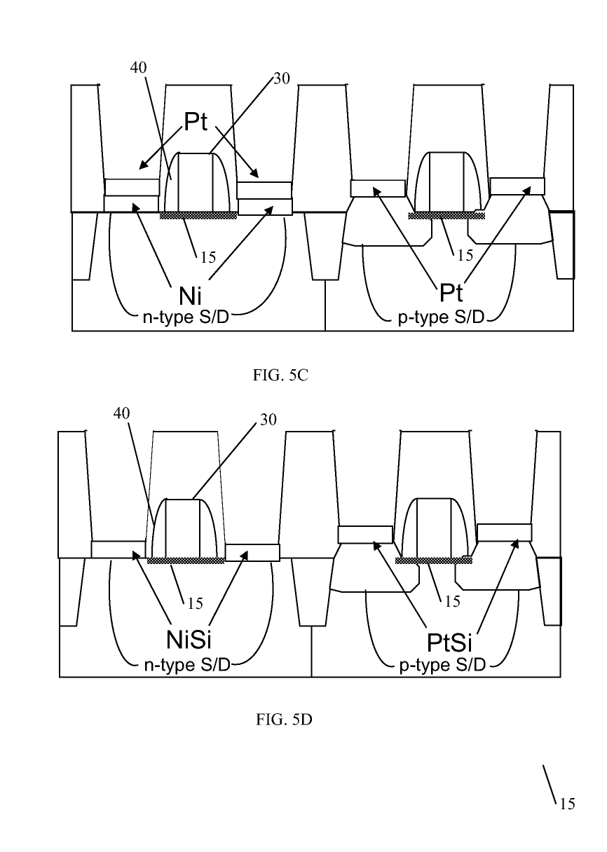

FIG. 4 shows a process flow 400 for the selective deposition of silicide source/drain contacts according to one embodiment. For reasons discussed below, selective deposition of metals to form silicides may provide contacts on SiGe or n-type Si substrate portions, excluding the p-type regions. In one embodiment, such selective deposition may be achieved by way of electroless deposition. FIGS. 5A-5D show various stages of selective deposition of silicide source/drain contacts according to the exemplary process of FIG. 4.

Process flow 400 begins with an electroless deposition of low or mid-gap WF metal over the n-type S/D (NMOS) region of a transistor (P410). As described below, electroless deposition is selective in not depositing on insulating mask materials or p-type Si or SiGe. Ni is an example of a metal that will electroless deposit on NMOS surface selectively, but other metals, such as Cr, Ti, W, Hf and others may be chosen according to FIG. 1. A nonselective deposition of high WF metal may be deposited by electroless process over both the NMOS and PMOS region of the device (P430).

The deposition over the NMOS region may be over a low or mid-gap WF metal previously deposited by the electroless process. No metal may be deposited on insulator surfaces via the electroless process. Pt may be chosen as the high WF metal, but other metals, such as Os and Ir may be deposited in alternative embodiments. The device may be annealed to form silicides (P450) at each S/D region. For example, NiSi may be formed over the NMOS region and PtSi may be formed over the PMOS region in one embodiment. A salicide etch may be applied (P470) to remove any unreacted metal (i.e., not forming a silicide during annealing) over the S/D regions.

FIG. 5A shows the device following process P410 where, for example, electroless Ni deposits selectively on the NMOS region of the S/D but not the PMOS region (or anywhere else). FIG. 5B shows the electroless deposited high WF metal (e.g., Pt) on the low WF metal (e.g., Ni) and the PMOS S/D contact region resulting from process block 430. FIG. 5C shows the device after annealing (P450), where NiSi forms in the NMOS S/D region, PtSi forms in the PMOS S/D region, but the Pt over the NiSi remains unreacted. FIG. 5D shows the NiSi contacts remaining over the NMOS S/D regions and PtSi contacts remaining over the PMOS S/D regions following the salicide etch (P470).

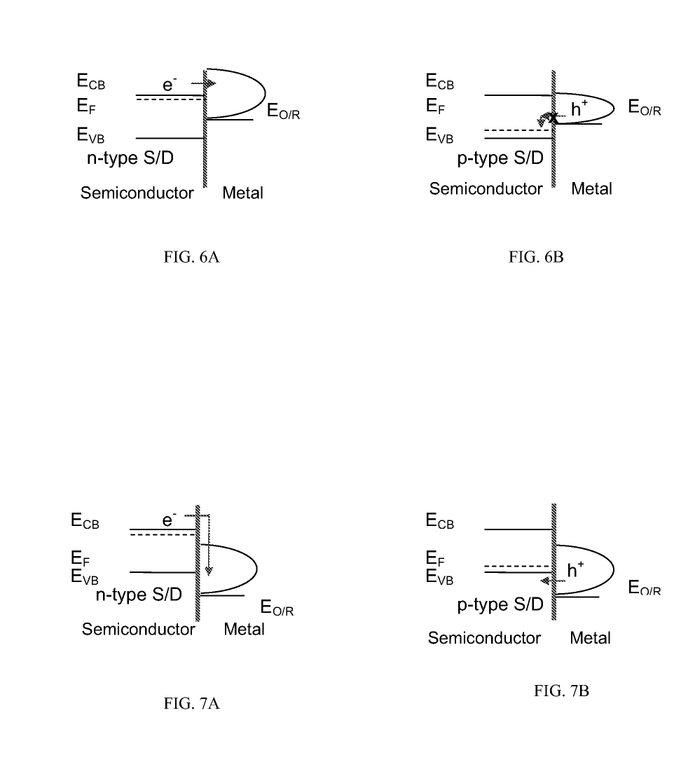

In the following, achieving selective electroless deposition of a low WF metal on NMOS, and a high WF metal on both NMOS and PMOS is described with reference to FIGS. 6 and FIG. 7. As provided earlier, a midgap metal has a reduction potential towards the middle of the Si and SiGe bandgaps. Reduction of the metal ion from an electroless bath solution can occur either via electron transfer from the substrate or hole injection. Since for n⁺⁺ Si, the Fermi level is near the conduction band edge, the reduction of a midgap metal may occur via electron injection from the substrate (FIG. 6A).

The Fermi level for p++ SiGe is near the valence band edge. No states may be available in the conduction band. Electron donation from the substrate cannot occur, and hole transfer may be blocked by the intrinsic barrier (FIG. 6B). Therefore, in some embodiments, self-initiated electroless deposition of a midgap metal is expected to occur on n⁺⁺ Si but not p⁺⁺ SiGe surfaces.

A high WF metal (e.g., Pt) has a reduction potential below the valence band edge of both the Si and SiGe bandgaps. Reduction of the metal in the electroless solution may occur via electron transfer from the substrate, or by hole injection, for example. In some embodiments, due to the higher reduction potential of Pt, deposition on n⁺⁺ Si may occur via electron donation, while on p⁺⁺ SiGe deposition may occur via hole injection (see FIGS. 7A and 7B). Therefore self-initiated electroless deposition of a large WF metal is expected to be non-selective and occur both on n⁺⁺ Si and p⁺⁺ SiGe surfaces.

The various embodiments described above have been presented by way of example and not by way of limitation. Thus, for example, while embodiments disclosed herein teach the formation of protective nitride cap by plasma deposition, other methods of providing the nitride protective cap are also within the scope of the claimed subject matter. Ni deposition may be accomplished by a variety of vacuum or plasma methods, or by way of employing electroplating techniques.

It should be understood that the processes, methods, and the order in which the respective elements of each method are performed are purely exemplary. Depending on the implementation, they may be performed in a different order or in parallel, unless indicated otherwise in the present disclosure.

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multi-chip package (such as a ceramic carrier that has either or both surface interconnections of buried interconnections).

In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Having thus described in detail embodiments of the present invention, it is understood that the invention defined by the appended claims is not to be limited by particular details set forth in the above description, as many apparent variations thereof are possible without departing from the spirit or scope thereof.

1. A method for forming dual salicide contacts comprises:
depositing a low or mid-gap work function metal selectively on an NMOS source/drain (S/D) region of a semiconductor device via electroless deposition;
depositing a high work function metal selectively over the low or mid-gap work function metal and a PMOS source/drain (S/D) region of a semiconductor device via electroless deposition;
annealing the semiconductor device to form a silicide of the low or mid-gap work function metal over the NMOS source/drain (S/D) region and a silicide of the high work function metal over the PMOS source/drain (S/D) region; and
performing a salicide etch to remove unreacted metals from selected regions of the substrate.

2. The method of claim 1, wherein the low or mid-gap work function metal comprises at least one or more of Ni, Zr, W, V, Rh, Cr, Ti, Ta, Nb, Hf, Gd, Y, and Cs.

3. The method of claim 1 wherein the high work function metal comprises at least one or more of Pt, Os, and Ir.

4. A dual salicide contact comprising:
an NMOS source/drain (S/D) region of a semiconductor substrate;
a PMOS source/drain (S/D) region of the semiconductor substrate;
a low or midgap work function metal selectively deposited on the NMOS source/drain (S/D) region via electroless deposition;
a high work function metal selectively deposited over the low or mid-gap work function metal and the PMOS source/drain (S/D) region of the semiconductor device via electroless deposition, wherein the substrate is annealed to form a silicide of the low or mid-gap work function metal over the NMOS source/drain (S/D) region and a silicide of the high work function metal over the PMOS source/drain (S/D) region, and wherein the unreacted low, mid-gap and high work function metals are removed with a SALICIDE etch.

5. The dual salicide contact of claim 4, wherein the low or mid-gap work function metal comprises at least one or more of Ni, Zr, W, V, Rh, Cr, Ti, Ta, Nb, Hf, Gd, Y, and Cs.

6. The dual salicide contact of claim 4, wherein the high work function metal comprises at least one or more of Pt, Os, and Ir.
